(19) United States
(12) Patent Application Publication
(10) Pub. No.: US 2009/0014751 A1
(43) Pub. Date: Jan. 15, 2009

(54) III-Nitride Semiconductor Light Emitting Device and Method for Manufacturing the Same

(76) Inventors: Chang-Tae Kim, Kyunggi-do (KR); Keuk Kim, Kyunggi-do (KR); Tae Kyung Yoo, Kyunggi-do (KR)

Correspondence Address: HARNESS, DICKEY, & PIERCE, P.L.C, 7700 Bonhomme, Suite 400, ST. LOUIS, MO, 63105, US

(21) Appl. No.: 11/795,995

(22) PCT Filed: Oct. 6, 2005
(86) PCT No.: PCT/KR2005/003319

§ 371 Date: May 19, 2008

(30) Foreign Application Priority Data
Oct. 6, 2004 (KR) 10-2004-0079508

(51) Int. Cl. H01L 33/00; H01L 21/00

(52) U.S. Cl. 257/103; 438/46; 257/E33.001; 257/E21.001

(57) ABSTRACT

Disclosed herein is a IE-nitride semiconductor light emitting device comprising a plurality of nitride semiconductor layers including a substrate and an active layer deposited on the substrate, in which the substrate is provided with protrusions to let the lights generated in the active layer emit out of the light emitting device and each of the protrusions has a first scattering plane and a second scattering plane, which are not parallel to each other.

### TECHNICAL FIELD

The present invention relates to a III-nitride semiconductor light emitting device and a method for manufacturing the same, and more particularly, a III-nitride semiconductor light emitting device and a method for manufacturing the same by employing a substrate with protrusions thereon to increase external quantum efficiency.

Here, the III-nitride semiconductor light emitting device means a light emitting device such as a light emitting diode comprising a compound semiconductor layer of AlₓGa_{y}In_{1-x-y}N (0≦x≦1, 0≦y≦1, x+y≦1), which may further comprise a compound of elements from other groups such as SiC, SiN and SiCN or a semiconductor layer of the compound.

### BACKGROUND ART

FIG. 1 is a view for explanation of a process, in which lights are repeatedly reflected and extinguished within a conventional light emitting device. When lights from an active layer 13 get out into the air (a refractive index=1.0), that is, escape from the upper part of the device, as represented as the light path 1, if a upper contact layer 14 is formed of GaN (a refractive index=2.5), the incidence angle should be a critical angle of 23.6° or less. Therefore, lights having an incidence angle of 23.6° or more are reflected into the inside of the device and fail to escape the device, as represented as the light path 2.

A similar phenomenon occurs between a lower contact layer 12 and a substrate 10. When the substrate 10 is formed of sapphire (a refractive index=1.8), it has a relatively big critical angle of 46.1°. However, lights having an incidence angle of 46.1° or more still return to the inside of the lower contact layer 12, as represented as the light path 3.

Therefore, only a small amount of lights escape from the device and the rest is locked in the device. Such process is repeated several times, lights are rapidly extinguished within the device.

However, when protrusions are provided on the substrate 10, as shown in FIG. 2, lights which fail to escape from the device can escape through a new light path changed by the side wall(s) of the protrusions, as represented by the light path 2.

For example, International Patent Publication No. WO 03/010831 by Nichia discloses the above-described technique and International Patent Publication No. WO 2005/015648 by the present inventors discloses a light emitting device, in which the protrusions are provided with steps to increase planes, upon which lights can be scattered.

### DISCLOSURE

### Technical Problem

Accordingly, the present invention has been made to solve the above-mentioned problems occurring in the prior art, and it is an object of the present invention to provide a III-nitride semiconductor light emitting device comprising protrusions having a light scattering plane enlarged to improve external quantum efficiency and a method for producing the same.

### Technical Solution

To accomplish the above objects of the present invention, according to the present invention, there is provided a III-nitride semiconductor light emitting device comprising a plurality of nitride semiconductor layers including a substrate and an active layer deposited on the substrate, in which the substrate is provided with protrusions to let the lights generated in the active layer emit out of the light emitting device and each of the protrusions has a first scattering plane and a second scattering plane, which are not parallel to each other.

Preferably, the angle formed by the substrate surface and the first scattering plane is less than 90° so that more lights can be emitted out of the light emitting device.

The size of the protrusion, the distance between the protrusions and the height of the protrusion are not particularly limited. However, when the size of each protrusion is increased or the distance between the protrusions is increased, the number of protrusions formed in the light emitting device is reduce, whereby the amount of the light emitted from the device my be reduced. When the distance between protrusions is too small or the height of each protrusion is too high, the epitaxial layer may not be stably grown on the substrate.

Also, according to the present invention, there is provided a III-nitride semiconductor light emitting device, in which the first scattering plane and the second scattering plane are formed by two etching processes and the second scattering plane is formed in the second etching process.

The etching is preferably performed by dry etching and usable etching masks include photo-resistor, polymers, BCB and the like, such as those whose the side wall angle can be readily changed.

Also, according to the present invention, there is provided a E-nitride semiconductor light emitting device, in which the first scattering plane and the second scattering plane are formed by using one etching mask.

Also, according to the present invention, there is provided a III-nitride semiconductor light emitting device, in which the first scattering plane and the second scattering plane are formed by one etching process.

Also, according to the present invention, there is provided a III-nitride semiconductor light emitting device, in which the first scattering plane and the second scattering plane are formed by using two etching masks.

Also, according to the present invention, there is provided a III-nitride semiconductor light emitting device, in which the two etching masks include a first etching mask and a second etching mask formed on the first etching mask and the second scattering plane is formed on the second etching mask.

Also, according to the present invention, there is provided a method for producing a III-nitride semiconductor light emitting device comprising a plurality of nitride semiconductor layers including a substrate and an active layer deposited on the substrate, in which the substrate is provided with protrusions to let the lights generated in the active layer emit out of the light emitting device and the protrusions are formed by the steps of:

(1) patterning an etching mask formed on the substrate;

(2) etching the substrate to remain a part of the patterned etching mask;

(3) heat-treating the remaining part of the etching mask so that the side wall of the mask is inclined; and

(4) etching the substrate using the thermally treated remaining etching mask as a mask.

Preferably, the method according to the present invention may further comprise a step to subject the patterned etching mask to a thermal treatment so that the side wall is inclined, prior to the step (2).

Also, according to the present invention, there is provided a method for producing a III-nitride semiconductor light emitting device comprising a plurality of nitride semiconductor layers including a substrate and an active layer deposited on the substrate, in which the substrate is provided with protrusions to let the lights generated in the active layer emit out of the light emitting device and the protrusions are formed by the steps of:

(1) forming a first etching mask on a substrate;

(2) forming a second etching mask on the first etching mask;

(3) patterning the second etching mask;

(4) subjecting the patterned second etching mask to a thermal treatment so that the side wall is inclined;

(5) removing the first etching mask without the patterned second etching mask formed thereon; and

(6) etching the substrate.

Also, according to the present invention, there is provided a method for producing a III-nitride semiconductor light emitting device comprising a plurality of nitride semiconductor layers including a substrate and an active layer deposited on the substrate, in which the substrate is provided with protrusions to let the lights generated in the active layer emit out of the light emitting device and the protrusions are formed by the steps of:

(1) forming a first etching mask on a substrate;

(2) forming a second etching mask on the first etching mask;

(3) patterning the first etching mask and the second etching mask; and

(4) subjecting the patterned second etching mask to a thermal treatment so that the side wall is inclined.

### ADVANTAGEOUS EFFECTS

According to the present invention, by forming protrusions having a first scattering plane and a second scattering plane on a substrate, it is possible to provide an enlarged scattering plane, whereby the light emission of the light emitting device to the outside is increased, causing improvement of the external quantum efficiency.

### DESCRIPTION OF DRAWINGS

Further objects and advantages of the invention can be more fully understood from the following detailed description taken in conjunction with the accompanying drawings in which:

FIG. 1 and FIG. 2 are views for explanation of problems involved in a conventional light emitting device;

FIG. 3 is a view showing a substrate of an embodiment of the light emitting device according to the present invention;

FIG. 4 is a view for explanation of a method for forming the substrate of the light emitting device according to the present invention;

FIG. 5 is a view for explanation of the change in the side wall of the photo-resistor according to temperature of thermal treatment;

FIG. 6 is a photograph of the substrate provided with protrusions on the surface according to the present invention;

FIG. 7 is an enlarged cross-sectional view of FIG. 6;

FIG. 8 to FIG. 10 are views showing other configurations of protrusions formed according to the present invention;

FIG. 11 is a view for explanation of another method for forming the light emitting device comprising protrusions according to the present invention;

FIG. 12 is a view for explanation of another method for forming the light emitting device comprising protrusions according to the present invention;

FIG. 13 is a view showing the III-nitride semiconductor light emitting device according to the present invention; and

FIG. 14 is a view showing an example of the etching mask pattern according to the present invention.

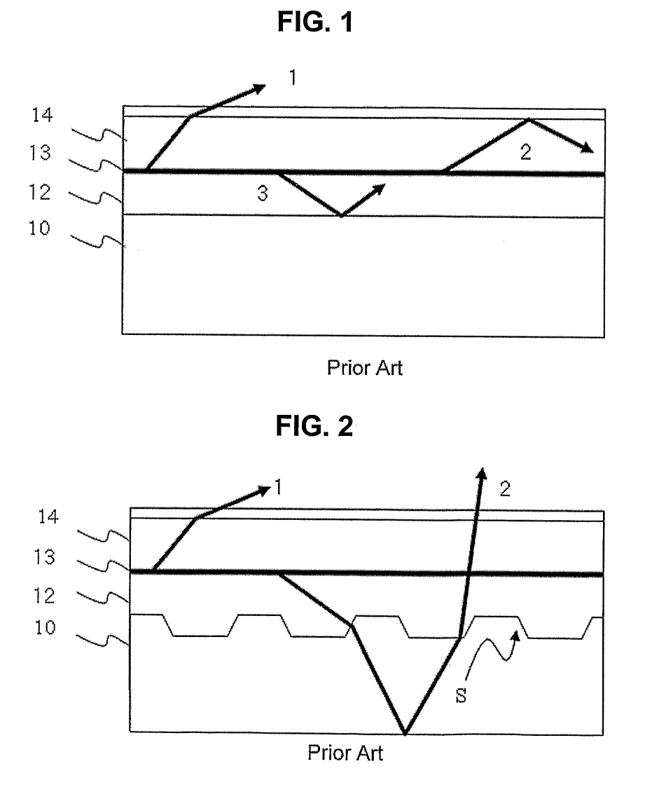

### MODE FOR INVENTION

Now, a preferred embodiment of the present invention is described in detail with reference to the attached drawings.

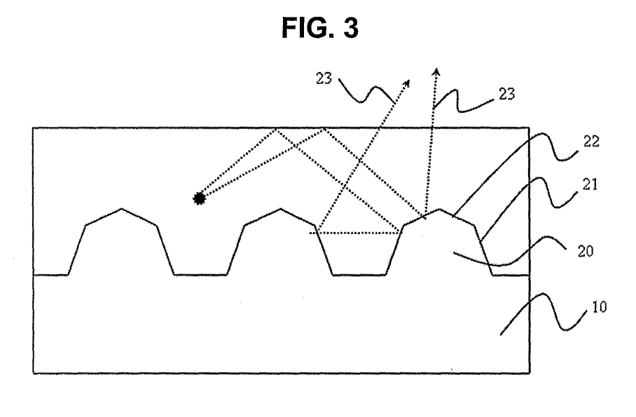

FIG. 3 is an example of a substrate of the light emitting device according to the present invention. The substrate 10 is provided with protrusions 20. The protrusion 20 includes a first scattering plane 21 and a second scattering plane 22. The first scattering plane 21 and the second scattering plane 22 allow the lights 23 generated in an active layer to be scattered out of the light emitting device.

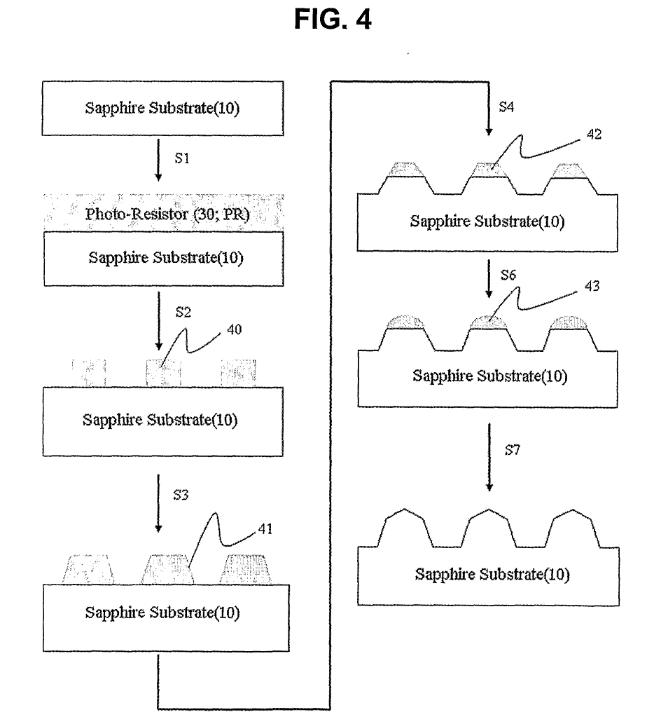

FIG. 4 is a view for explanation of a method for forming the substrate of the light emitting device according to the present invention. Firstly, a photo-resistor 30 is applied on a substrate 10 (S1). The substrate 10 used in this example is a sapphire substrate. The photo-resistor 30 is model No. AZGXR601 of Clariant and is applied to a thickness of about 2.7 μm.

Next, the applied photo-resistor 30 is patterned by exposure and development using a photomask (S2). In this example, it is patterned in a hexagonal shape, as shown in FIG. 14, and a length of a side of the hexagon and a distance (W) between patterns are 2 μm, respectively. The pattern may include s circle, s hexagon, an oval, a square, a triangle, a trapezoid, a rhombus, a parallelogram and the like. In case of the hexagonal pattern, it is advantageous to densely form the pattern in a limited area.

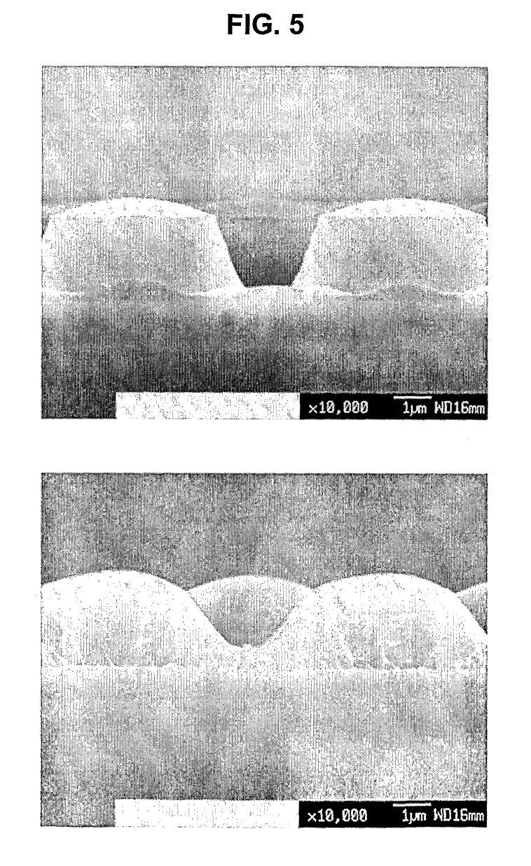

Next, the patterned photo-resistor 40 is subjected to a thermal treatment to have the side wall 41 to be inclined (S3). Here, referring to the change in the inclination angle of the side wall 41 of the photo-resistor, shown in FIG. 5, the angle formed by the side wall 41 and the substrate surface is decreased when the temperature of the thermal treatment is increased. The primary thermal treatment in this example is performed for 5 minutes at 120° C., as shown in FIG. 5.

After the primary thermal treatment to incline the side wall 41 of the pattern 40, the substrate 10 is dry-etched (S4). Here, the dry etching is performed by plasma, in which the plasma is excited by using a chlorine-containing gas (Cl₂, BCl₃, CCl₄, HCl). The excitation of plasma includes ICP (Inductive Coupled Plasma), CCP (Capacitive Coupled Plasma), ECR (Electron-Cyclotron Resonant) and the like. In this example, the etching is performed using a ICP-RIE (Inductive Coupled Plasma-Reactive Ion Etching) equipment with BCl₃ gas. The substrate 10 is etched by 550 nm, in which the etching ratio of the substrate 10 and the pattern 40 is approximately 1:2. In this drying etching process, all the pattern 40 with the side wall 41 formed thereon is not etched and a part 42 of the pattern is reserved to act as an etching mask in the secondary etching process, described below.

The reserved part 42 of the pattern 40 is subjected to a secondary thermal treatment (S5). It is the purpose of the secondary thermal treatment to alter the shape of the reserved part 42 of the pattern which will act as an etching mask in the secondary dry etching so that a secondary scattering plane 22 is distinguished from a first scattering plane 21, as shown in FIG. 3. In this example, the secondary thermal treatment is performed for 5 minutes at 155° C.

Next, the substrate 10 is secondarily dry-etched using the part 42 of the pattern, the shape of which has been changed by the secondary thermal treatment, as an etching mask. Preferably, the etching is performed until the part 43 of the pattern is completely removed. It is because an additional process is required to remove the part 43 remaining after the etching. In this example, the substrate 10 is further etched about 800 nm to completely remove the part 43 of the pattern.

FIG. 5 is a view for explanation of the change in the side wall of the photo-resistor, showing photographs the pattern after thermal treatment at 120° C. and 140° C. for 5 minutes. It is noted that the inclination of the side wall is decreased when the temperature is increased.

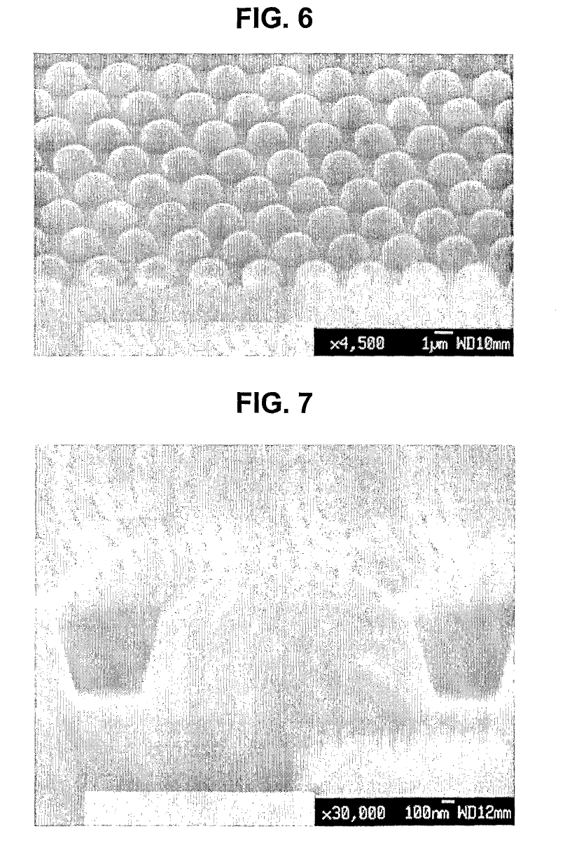

FIG. 6 is a photograph of the substrate provided with protrusions on the surface according to the present invention and FIG. 7 is an enlarged cross-sectional view of FIG. 6. In this example, protrusions are regularly formed on the substrate.

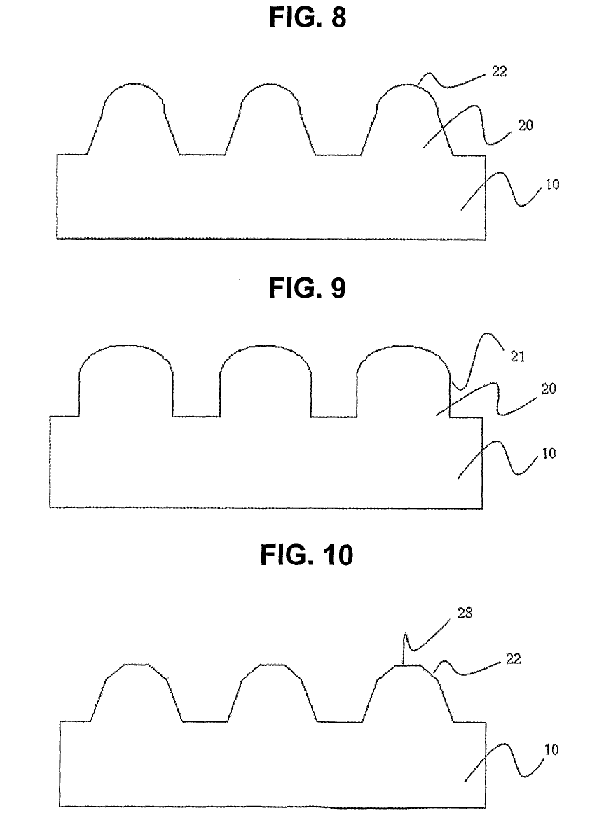

FIG. 8 to FIG. 10 are views showing other configurations of protrusions formed according to the present invention. FIG. 8 shows protrusions 20 with a second scattering plane 22 not being angled. FIG. 9 shows protrusions 20 with a first scattering plane 21 being perpendicular to the substrate 10, in which the primary thermal treatment may be omitted. FIG. 10 shows protrusions 20 with the upper part of the second scattering plane 22 not being etched. These protrusions are formed when the part 43 of the pattern is not removed by the secondary dry etching.

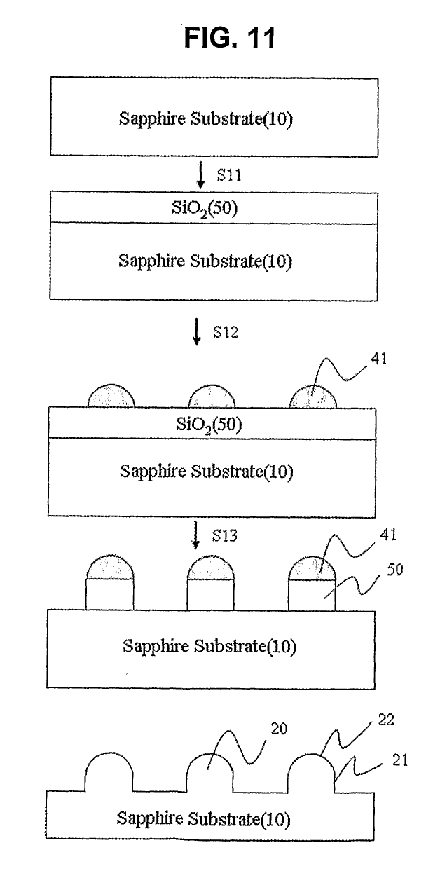

FIG. 11 is a view for explanation of another method for forming the light emitting device employing protrusions according to the present invention. A second etching mask 50 is formed on a sapphire substrate 10 (S11) and a is thermally treated pattern 41 is formed thereon (S12). The part of the second etching mask 50, where the pattern 41 is not formed, is removed (S13) and the pattern 41 and the second etching mask 50 are removed (S14) to form protrusions 20 having a first scattering plane 21 and a second scattering plane 22. The second etching mask 50 may include a metal such as Ni, Cr, W, V, Ir, Pt and the like and an insulator such as SiO₂, NiO, MgO, Si₃N₄ and the like. This method is advantageous when the photo-resistor shows a significantly more rapid etching rate than the substrate under conditions of the dry etching process. Two etching mask are used. The protrusions may be formed by one etching process.

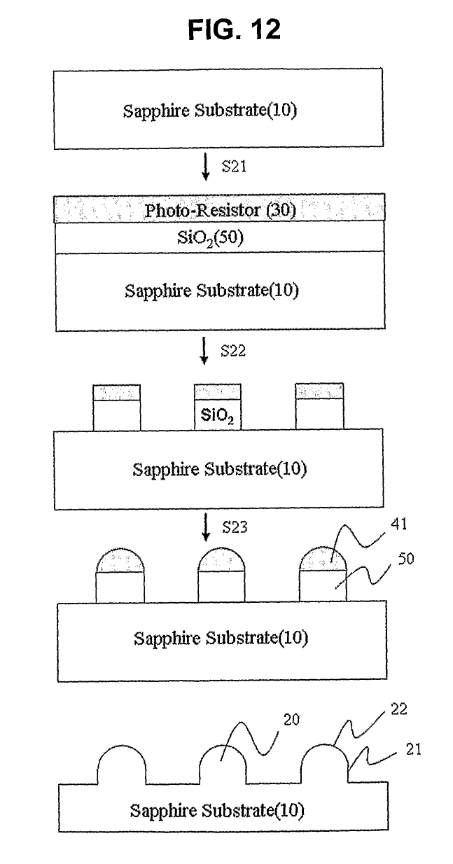

FIG. 12 is a view for explanation of another method for forming the light emitting device comprising protrusions according to the present invention. Unlike the method described in FIG. 11, a second etching mask 50 and a photo-resistor 30 are firstly formed on a substrate 10 (S21), patterned (S22), and subjected to a thermal treatment to form a thermally treated pattern 41 (S23). Then, the substrate 10 is etched (S24) to form protrusions 20.

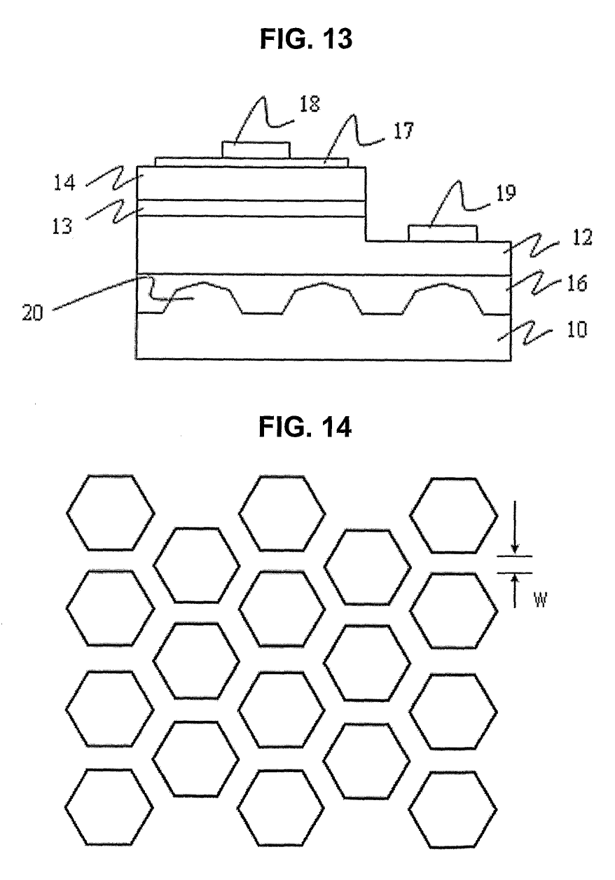

FIG. 13 FIG. 13 is a view showing the III-nitride semiconductor light emitting device according to the present invention. The III-nitride semiconductor light emitting device is formed by sequentially depositing a buffer layer 16, a lower contact layer 12 contacting a n-side electrode 19, an active layer 13 for generating light by recombination of electron and hole, a upper contact layer 15 contacting p-side electrodes 17 and 18 on a substrate 10.

The substrate 10 is preferably a sapphire substrate but also may include silicone or silicon carbide. The buffer layer 16 is preferably an Al(x)Ga(y)N buffer layer grown at a temperature of 200 to 900° C., disclosed in U.S. Pat. No. 5,290,393, or a SiC buffer layer disclosed in International Patent Publication No. WO 2005/053042 by the present inventors. The lower contact layer 12 and the upper contact layer 15 are preferably formed of AlₓGa_{y}In_{1-x-y}N (0≦x≦1, 0≦y≦1, x+y≦1) and comprise a plurality of layers having different compositions or doping concentrations. The active layer 13 is preferably formed of a single- or multiple-quantum well layer of AlₓGa_{y}In_{1-x-y}N (0≦x≦1, 0≦y≦1, x+y≦1).

The protrusions are formed by several methods as described above. However, the surface roughness of the protrusions, that is the roughness of the first scattering plane and the second scattering plane, is not influenced by any of the described methods.

1. A III-nitride semiconductor light emitting device comprising a plurality of nitride semiconductor layers including a substrate and an active layer deposited on the substrate which creates lights by recombining an electron and a hole, in which the substrate is provided with protrusions to let the lights generated in the active layer emit to the outside of the light emitting device and each of the protrusions has a first scattering plane and a second scattering plane, which are not parallel to each other.

2. The device of claim 1, in which the first scattering plane and the second scattering plane are formed through two etching processes and the second scattering plane is formed in the second etching process.

3. The device of claim 1, in which the first scattering plane and the second scattering plane are formed by using one etching mask.

4. The device of claim 3, in which the etching mask is a photo-resistor.

5. The device of claim 1, in which the first scattering plane and the second scattering plane are formed by one etching process.

6. The device of claim 1, in which the first scattering plane and the second scattering plane are formed by using two etching masks.

7. The device of claim 6, in which the two etching masks comprise of a first etching mask and a second etching mask formed on the first etching mask and the second scattering plane is formed on the second etching mask.

8. A method for producing a III-nitride semiconductor light emitting device comprising a plurality of nitride semiconductor layers including a substrate and an active layer deposited on the substrate which creates lights by recombining an electron and a hole, in which the substrate is provided with protrusions to let the lights generated in the active layer emit to the outside of the light emitting device and the protrusions are formed by the steps of:
(1) patterning an etching mask formed on the substrate;
(2) etching the substrate to remain a part of the patterned etching is mask;
(3) heat-treating the remaining part of the etching mask so that the side wall of the mask is inclined; and
(4) etching the substrate by using a part of heat-treated etching mask as a etching mask.

9. The method of claim 8, which further comprises a step to heat-treat the patterned etching mask so that the side wall is inclined, prior to the step (2).

10. The method of claim 8, in which the part of the heat-treated etching mask in the step (4) is completely removed by etching.

11. A method for producing a III-nitride semiconductor light emitting device comprising a plurality of nitride semiconductor layers including a substrate and an active layer deposited on the substrate which creates lights by recombining an electron and a hole, in which the substrate is provided with protrusions to let the lights generated in the active layer emit to the outside of the light emitting device and the protrusions are formed by the steps of:
(1) forming a first etching mask on a substrate;
(2) forming a second etching mask on the first etching mask;
(3) patterning the second etching mask;
(4) heat-treating the patterned second etching mask so that the side wall is inclined;
(5) removing the first etching mask without the patterned second etching mask formed thereon; and
(6) etching the substrate.

12. A method for producing a III-nitride semiconductor light emitting device comprising a plurality of nitride semiconductor layers including a substrate and an active layer deposited on the substrate which creates lights by recombining an electron and a hole, in which the substrate is provided with protrusions to let the lights generated in the active layer emit to the outside of the light emitting device and the protrusions are formed by the steps of:
(1) forming a first etching mask on a substrate;
(2) forming a second etching mask on the first etching mask;
(3) patterning the first etching mask and the second etching mask; and
(4) heat-treating the patterned second etching mask so that the side wall is inclined.

13. The device of claim 1, in which the first scattering plane is a surface perpendicular to the substrate.

14. The device of claim 1, in which the second scattering plane is a curved surface.
